(19) United States
(12) Patent Application Publication
(10) Pub. No.: US 2021/0408002 A1
(43) Pub. Date: Dec. 30, 2021

(54) DOUBLE WALL CAPACITORS AND METHODS OF FABRICATION

(71) Applicant: Intel Corporation

(72) Inventors: Travis W. LaJoie, Forest Grove, OR (US); Abhishek A. Sharma, Hillsboro, OR (US); Van Le, Beaverton, OR (US); Chieh-Jen Ku, Hillsboro, OR (US); Pei-Hua Wang, Hillsboro, OR (US); Bernhard Sell, Portland, OR (US); Juan G. Alzate-Vinasco, Tigard, OR (US)

(73) Assignee: Intel Corporation, Santa Clara, CA (US)

(21) Appl. No.: 16/914,152

(22) Filed: Jun. 26, 2020

(51) Int. Cl. H01L 27/108

(52) U.S. Cl. CPC H01L 27/10808; H01L 27/10852; H01L 27/10826

(57) ABSTRACT

An integrated circuit capacitor array includes a plurality of first electrodes, wherein individual ones of the first electrodes are substantially cylindrical with a base over a substrate and an open top end over the base. A first dielectric material layer spans a distance between the first electrodes but is absent from an interior of the first electrodes, where the first dielectric material layer is substantially planar and bifurcates a height of first electrodes. A second dielectric material layer lines the interior of the first electrodes, and lines portions of an exterior of the first electrodes above and below the first dielectric material layer and a second electrode is within the interior of the first electrodes and is around the exterior of the first electrodes above and below the first dielectric material layer.

### BACKGROUND

Embedded DRAM (eDRAM) memory utilizes a capacitor coupled with a single transistor to store charge. With scaling in transistor dimensions the geometry of the capacitor plays an important role in maintaining a sufficiently large capacitance that is advantageous for integrated circuit applications. Thus, innovative schemes for capacitor designs that overcome spatial limitations in a variety of transistor architectures is highly desirable.

### BRIEF DESCRIPTION OF THE DRAWINGS

FIG. 1 illustrates a flow diagram for a method to fabricate a double wall capacitor in accordance with an embodiment of the present disclosure.

FIG. 2 illustrates a cross-sectional illustration of an IC structure including a multilayer dielectric stack formed above a device structure.

FIG. 3A is a cross-sectional illustration of the structure of FIG. 2 following the process to etch each of the layers in the multilayer dielectric stack and form a plurality of openings.

FIG. 3B is a plan-view illustration of the structure in FIG. 3A.

FIG. 4A is a cross-sectional illustration of the structure in FIG. 3A following the formation of a plurality of bottom electrodes.

FIG. 4B is a plan-view illustration through a line A-A′ of the structure in FIG. 4A.

FIG. 5A illustrates the plan-view illustration of the structure in FIG. 4B following the formation of a mask and following the process to etch a plurality of layers in the multilayer dielectric stack.

FIG. 6A illustrates plan-view illustration of the structure in FIG. 5B following the removal of a plurality of dielectric layers under an insulator layer of the multilayer dielectric stack.

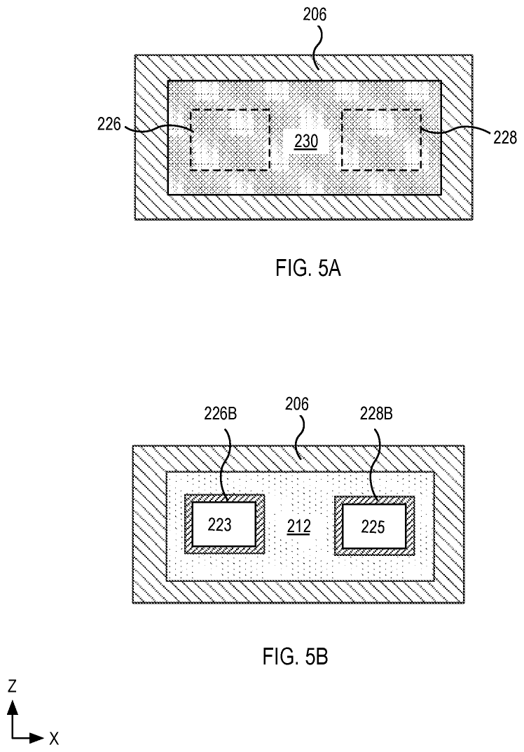

FIG. 5B illustrates the structure of FIG. 5A following the removal of a mask.

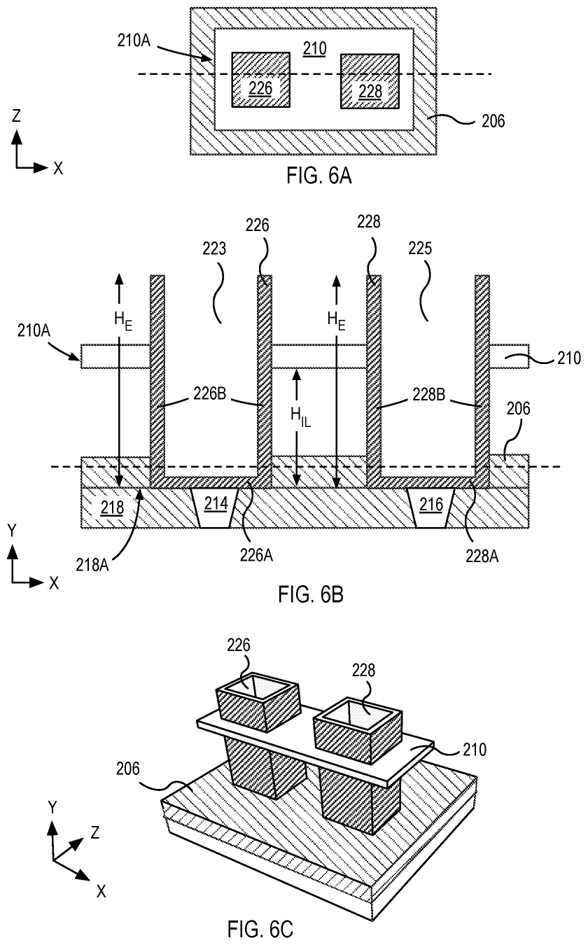

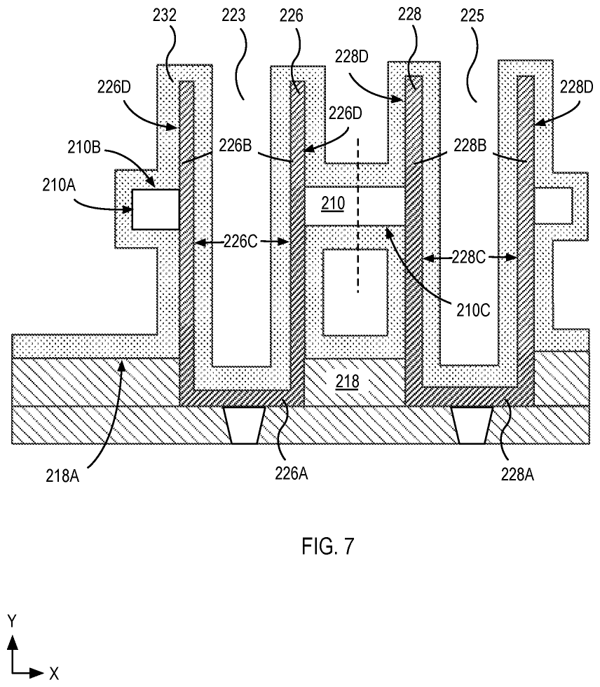

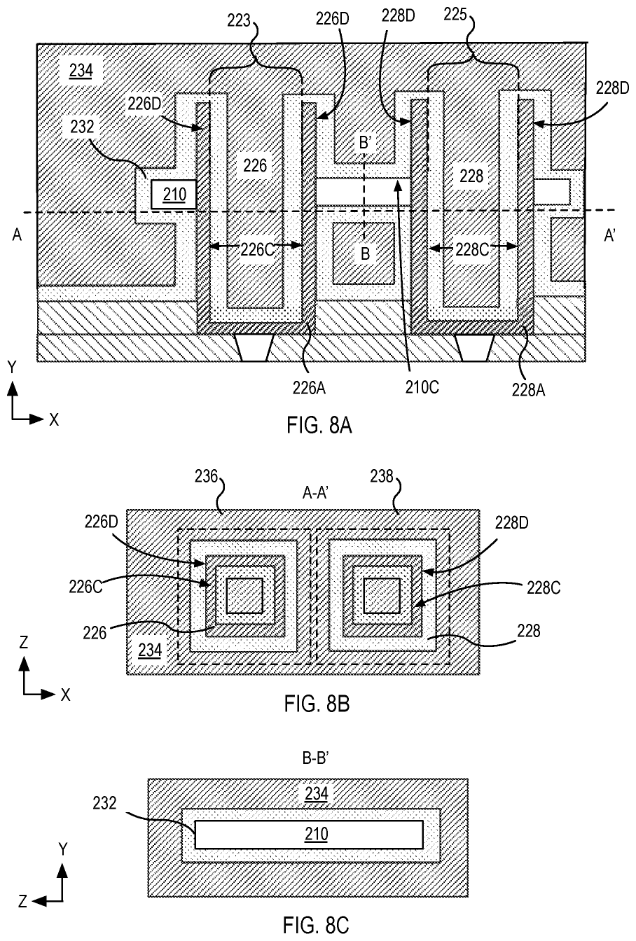

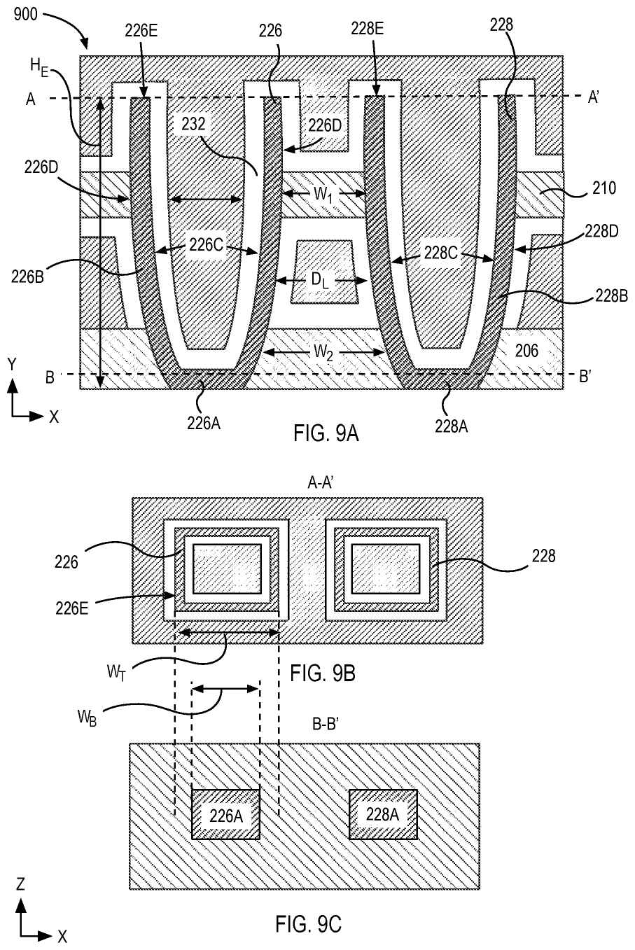

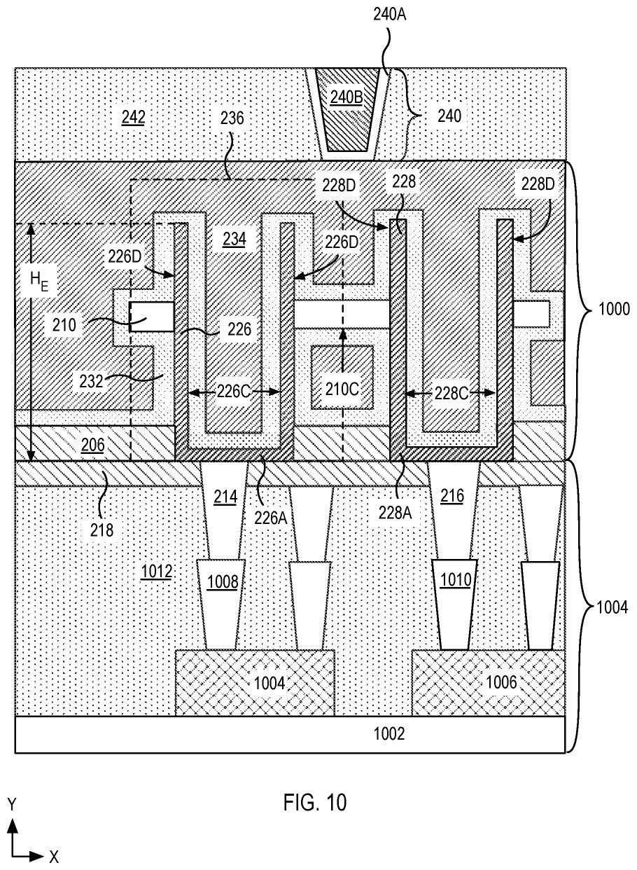

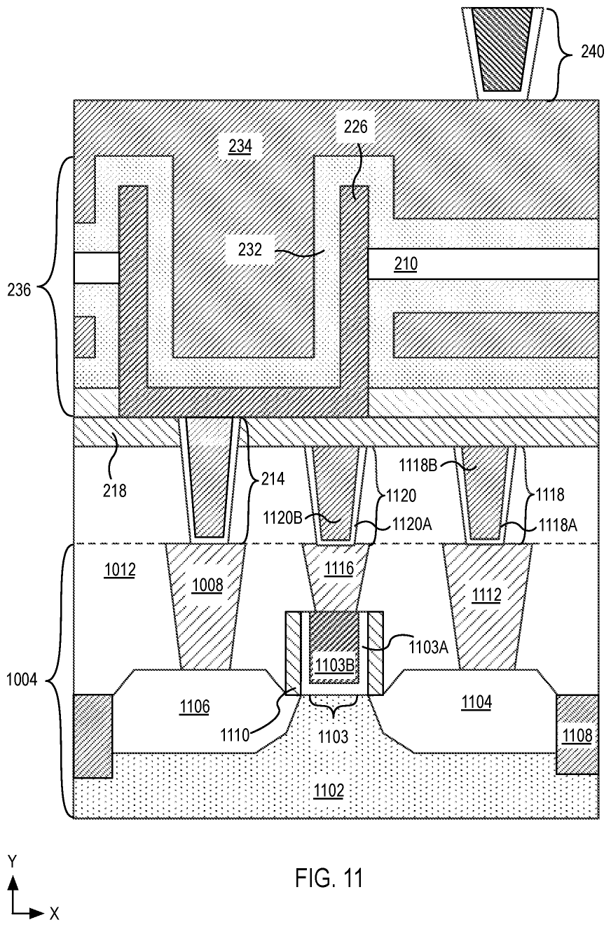

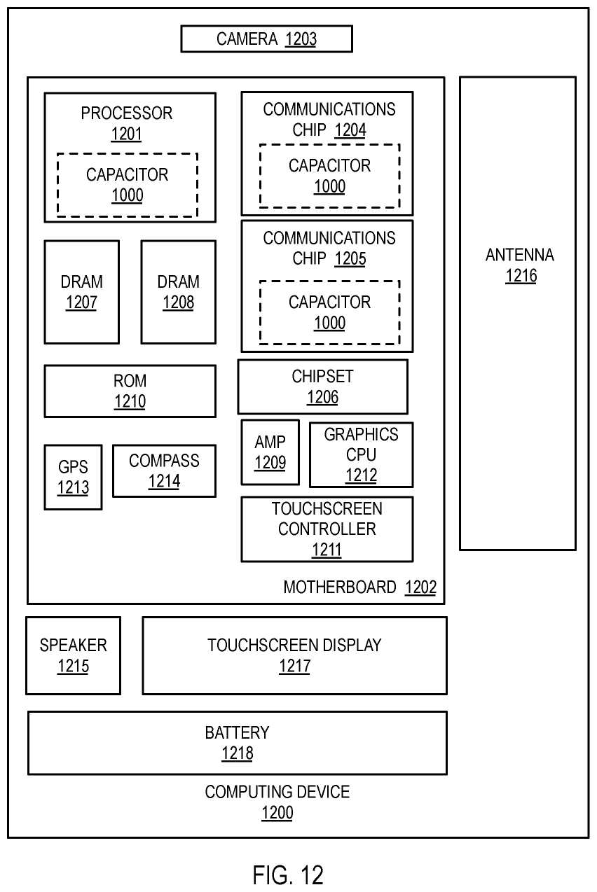

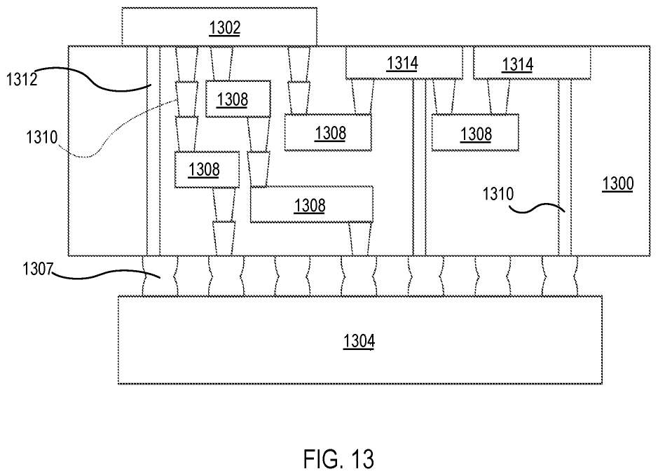

FIG. 6B is a cross-sectional illustration of the plan view structure in FIG. 6A, along the line A-A′.

FIG. 6C is an isometric illustration of the structure in FIG. 6B.

FIG. 7 illustrates the structure of FIG. 6B following the formation of a dielectric insulator on exposed surfaces of the plurality of bottom electrodes and on exposed surfaces of the insulator layer.

FIG. 8A illustrates the structure of FIG. 7 following the formation of an electrode layer on the dielectric insulator to complete the fabrication of a plurality of double wall capacitors, in accordance with an embodiment of the present disclosure.

FIG. 8B illustrates a plan view along a line A-A′ of the structure in FIG. 8A.

FIG. 8C is a cross-sectional illustration along a line B-B′ of the structure in FIG. 8A

FIG. 9A is a cross sectional illustration of an integrated circuit capacitor array, where the plurality of bottom electrodes have sidewalls that are curved, in accordance with an embodiment of the present disclosure.

FIG. 9B is a plan-view illustration through the line A-A′ of the structure in FIG. 9A.

FIG. 9C is a plan-view illustration through the line B-B′ of the structure in FIG. 9A.

FIG. 10 illustrates the structure of FIG. 8 following the formation of a conductive interconnect in contact with the electrode layer.

FIG. 11 is a cross-sectional illustration of a double walled capacitor coupled with a transistor, in accordance with an embodiment of the present disclosure.

FIG. 12 illustrates a computing device in accordance with embodiments of the present disclosure.

FIG. 13 illustrates an integrated circuit (IC) structure that includes one or more embodiments of the present disclosure

### DESCRIPTION OF THE EMBODIMENTS

Double wall capacitors and methods of fabrication are described. In the following description, numerous specific details are set forth, such as structural schemes and detailed fabrication methods in order to provide a thorough understanding of embodiments of the present disclosure. It will be apparent to one skilled in the art that embodiments of the present disclosure may be practiced without these specific details. In other instances, well-known features, such as transistor operations and switching operations associated with embedded memory, are described in lesser detail in order to not unnecessarily obscure embodiments of the present disclosure. Furthermore, it is to be understood that the various embodiments shown in the Figures are illustrative representations and are not necessarily drawn to scale.

In some instances, in the following description, well-known methods and devices are shown in block diagram form, rather than in detail, to avoid obscuring the present disclosure. Reference throughout this specification to “an embodiment” or “one embodiment” or “some embodiments” means that a particular feature, structure, function, or characteristic described in connection with the embodiment is included in at least one embodiment of the disclosure. Thus, the appearances of the phrase “in an embodiment” or “in one embodiment” or “some embodiments” in various places throughout this specification are not necessarily referring to the same embodiment of the disclosure. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example, in the context of materials, one material or material disposed over or under another may be directly in contact or may have one or more intervening materials. Moreover, one material disposed between two materials may be directly in contact with the two layers or may have one or more intervening layers. In contrast, a first material “on” a second material is in direct contact with that second material/material. Similar distinctions are to be made in the context of component assemblies. As used throughout this description, and in the claims, a list of items joined by the term “at least one of” or “one or more of” can mean any combination of the listed terms.

The term “adjacent” here generally refers to a position of a thing being next to (e.g., immediately next to or close to with one or more things between them) or adjoining another thing (e.g., abutting it).

The term “signal” may refer to at least one current signal, voltage signal, magnetic signal, or data/clock signal. The meaning of “a,” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

As used throughout this description, and in the claims, a list of items joined by the term “at least one of” or “one or more of” can mean any combination of the listed terms. Unless otherwise specified in the explicit context of their use, the terms “substantially equal,” “about equal” and “approximately equal” mean that there is no more than incidental variation between two things so described. In the art, such variation is typically no more than +/−10% of a predetermined target value.

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

In semiconductor devices such as DRAMs (Dynamic Random-Access Memory), each memory cell includes one transistor and one capacitor. In eDRAMs, cells require periodic reading and refreshing. Owing to the advantages of low price-per-unit-bit, high integration, and ability to simultaneously perform read and write operations, eDRAMs have enjoyed widespread use in commercial applications. The ability to easily detect the ‘1’ and ‘0’ states of the memory depends to a large extent on the size of the capacitor in the eDRAM cell. Larger capacitors allow easier signal detection. Also, since DRAM's are volatile, they require constant refreshing. The frequency of refresh is also reduced as the capacitance increases. Furthermore, a phenomenon referred to as “soft error” can be caused in eDRAM devices by a loss of charge that was stored in a capacitor due to external factors, thereby causing malfunction of eDRAMs. Occurrence of soft error may be prevented by enhancing the total capacitance of a capacitor.

Furthermore, with scaling of transistors, the space available for a capacitor above each transistor may be reduced. Hence, to increase the charge on the capacitor, a high-K dielectric material can be implemented between two capacitor electrodes. To further increase capacitance the geometry of the capacitor can include a plurality of concentric electrodes, separated by a high-K dielectric, formed within a trench in a dielectric material (or a double wall trench capacitor). However, as spacing between successive capacitors are reduced (because of closely packed transistors), the trench which houses traditional double wall trench capacitors may be also scaled to avoid shorting. This may limit the total capacitance that can be obtained from traditional double wall trench capacitors in a capacitor array in a tight pitch geometry.

The inventors have found that the total capacitance of a capacitor array may be increased by advantageously utilizing the space between any two or more neighboring capacitors to incorporate a first of two electrodes of each of the capacitors. Furthermore, in a given capacitor array, the first electrode of each capacitor may extend continuously from one capacitor to the next to advantageously utilize a single terminal contact. A second of the two electrodes of each capacitor may be coupled with a terminal of each of the transistors. The capacitor array further includes a dielectric, such as a high-K dielectric between the first and the second electrodes. The high-K dielectric may also be continuous between the two or more capacitors. The transistors that are individually coupled with each capacitor may be operated in unison relative to the terminal contact to simultaneously charge and discharge the capacitors.

In accordance with an embodiment of the present disclosure, an integrated circuit capacitor array includes a plurality of first electrodes, wherein individual ones of the first electrodes are substantially cylindrical with a base over a substrate and an open top end over the base. The capacitor array further includes a first dielectric material layer spanning a distance between the first electrodes and absent from an interior of the first electrodes, wherein the first dielectric material layer is substantially planar and bifurcates a height of first electrodes. The first dielectric material may provide mechanical support for substantially tall first electrodes. The capacitor array further includes a second dielectric material layer, where the second dielectric material layer lines the interior of the first electrodes, and lines portions of an exterior of the first electrodes above and below the first dielectric material layer. A second electrode and is around the exterior of the first electrodes, above and below the first dielectric material layer, and within the interior of the first electrodes to increase capacitance.

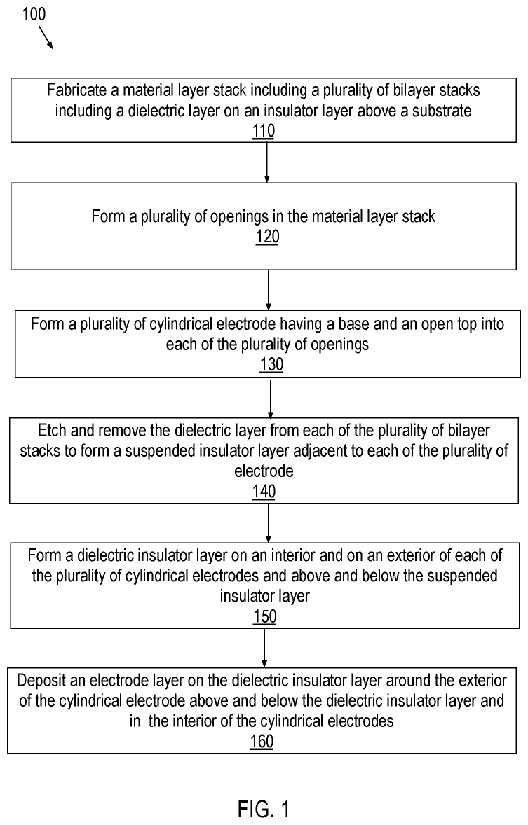

FIG. 1 illustrates a flow diagram for a method to fabricate an integrated circuit capacitor array, in accordance with an embodiment of the present disclosure. The method 100 begins at operation 110 by fabricating a material layer stack above a substrate, where the material layer stack includes a first insulator layer, a first dielectric layer on the first insulator, a second insulator layer on the first dielectric layer and a second dielectric layer on the second insulator layer. The method 100 continues at operation 120 with patterning a plurality of openings in the material layer stack. The method 100 continues at operation 130 with depositing a first electrode layer into each of the plurality of openings to form a plurality of cylindrical electrodes with a base over the substrate and an open top end over the base. The method 100 continues at operation 140 with etching the first dielectric and the second dielectric selectively to the cylindrical electrodes, to the first insulator and to the second insulator layer, where the etching forms a suspended second insulator layer spanning a distance between the cylindrical electrodes. The method 100 continues at operation 150 with the deposition of a dielectric insulator layer to line the interior of the cylindrical electrodes, and lines portions of an exterior of the cylindrical electrodes above and below the suspended second insulator layer. The method concludes at operation 160 with the deposition of a second electrode layer on the dielectric insulator layer filling the interior of the cylindrical electrodes, around the exterior of the cylindrical electrodes above and below the suspended second insulator layer.

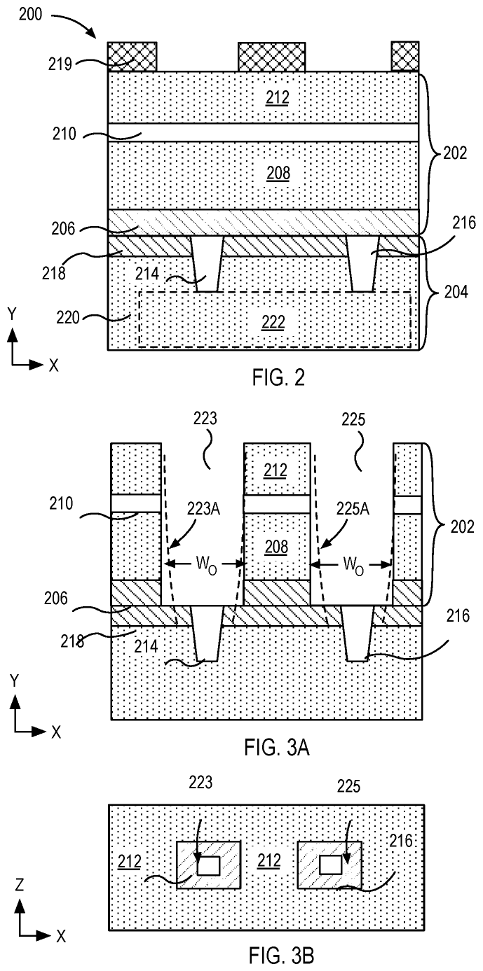

FIG. 2 is a cross-sectional illustration of an IC structure 200 including a multilayer dielectric stack 202 formed above a device structure 204. The multilayer dielectric stack 202 includes an insulator layer 206, a dielectric 208 on the insulator layer 206, an insulator layer 210 on the dielectric 208, capped by a dielectric 212 on the insulator layer 210.

In an embodiment, insulator layer 206 includes a material that facilitates support for an electrode structure and as an etch stop. In the illustrative embodiment, the insulator layer 206 is formed above an interconnect 214, a second interconnect 216 and a dielectric 218 adjacent to the interconnect 214 and interconnect 216. In an embodiment, the insulator layer 206 is blanket deposited by a (PECVD) or a chemical vapor deposition (CVD) process. In an embodiment, the insulator layer 206 includes silicon and nitrogen, for example, silicon nitride. In some embodiments, the deposition process involves doping the insulator layer 206 with carbon. The percent of carbon in the insulator layer 206 can be controlled during the deposition process and ranges between 2 and 30 atomic percent of the dielectric 208. In exemplary embodiments, the interconnects 214 and 216 include copper. Presence of nitrogen and carbon in the insulator layer 206 can prevent diffusion of copper from the underlying interconnects 214 and 216. An insulator layer 206 including silicon nitride is also advantageous when patterning and etching exposes a feature that includes copper. For example, where interconnects 214 and 216 include copper, patterning insulator layer 206 will reveal copper interconnects 214 and 216. A silicon nitride material can be etched with etch chemistry that may not corrode copper, when the etch exposes underlying copper features. Regardless of the deposition process, the insulator layer 206 may be deposited to a thickness between 10 nm and 20 nm, for example.

A mask 219 may be formed on the dielectric 212. The mask 219 defines locations for bottom electrodes to be formed.

In the illustrative embodiment, the interconnect structures 214 and 216 are also adjacent to a dielectric 220 below dielectric 218. In an embodiment, dielectric 218 includes a material that is the same or substantially the same as the material of insulator layer 206. Dielectric 220 includes a material that provides electrical isolation such as silicon and at least one or more of oxygen, nitrogen or carbon. The device structure 204 further includes a device region 222 having devices such as transistors, where each transistor is coupled with an interconnect structure 214 or 216.

FIG. 3A is a cross-sectional illustration of the structure of FIG. 2 following the process to etch each of the layers in the multilayer dielectric stack 202 and form openings 223 and 225. In an embodiment, a plasma etch process is utilized to etch the dielectric 212, the insulator layer 210, the dielectric 208 and the insulator layer 206. The plasma etch, for example, may be continued to etch and expose the interconnects 214 and 216 and the dielectric 218. In an embodiment, the material of the insulator layer 206 is different from the material of the dielectric 218 to prevent etching into the dielectric 218 and exposing sides of the interconnects 214 and 216. For example, the insulator layer 206 and the dielectric 218 may both include silicon and nitrogen but differing concentrations of carbon which can facilitate etch selectivity between them. It is to be appreciated that insulator layer 206 may be etched by a chemistry to includes no corrosive chemistry to avoid re-sputtering of any material of the interconnects 214 and 216.

The openings 223 and 225 have a cylindrical profile. As shown profiles of the opening 223 and 225 may be substantially vertical with respect to an uppermost surface 218A of the dielectric 218. In an embodiment, the openings 223 and 225 each have a width, W_{O}. W_{O} may be between 30 nm and 100 nm for example. In other embodiments, the openings 223 and 225 may be curved (as indicated by dashed lines 223A and 225A, respectively) and will be discussed in FIG. 9A, below.

FIG. 3B is a plan-view illustration of the structure in FIG. 3A. In the illustrative embodiment, the openings 223 and 225 have a rectangular plan view profile. In other embodiments, the openings 223 and 225 have a circular or elliptical plan view profile.

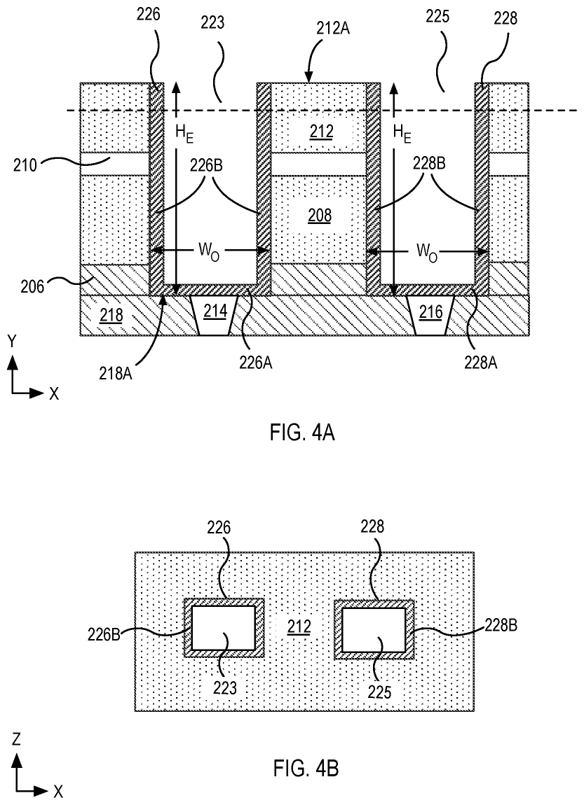

FIG. 4A is a cross-sectional illustration of the structure in FIG. 3A following the formation of a plurality of bottom electrodes. In an embodiment, a conductive layer is blanket deposited into the openings 223 and 225, on the uppermost surface 212A of the dielectric 212, on the interconnects 214 and 216, and on the dielectric 218. The conductive layer may include a material that can adhere to sidewalls of the dielectric 208 and 212, uppermost surface 218A of dielectric 218 and on sidewalls of insulator layers 210 and 206 in each of the openings 223 and 225. Adhesion to sidewalls of insulator layer 206 is advantageous for formation of substantially tall electrodes, such as for example taller than 100 nm. The conductive layer may be deposited to a thickness between 10 nm and 20 nm. In embodiments, the conductive layer includes titanium, tantalum ruthenium, nitrides of tantalum (for e.g., tantalum nitride) or nitrides of titanium (for e.g., titanium nitride).

After deposition, a sacrificial layer may be deposited on the conductive layer and a planarization process may be carried out to remove the sacrificial layer and the conductive layer from above the uppermost surface 212A. After the planarization process, the sacrificial layer is removed forming electrode 226 in opening 223 and electrode 228 in opening 225. As shown, the electrodes 226 and 228 each have a cylindrical shape that follows the contours of the openings 223 and 225, respectively. The cylindrical shape of electrodes 226 and 228 may have a rectangular plan view profile as illustrated in FIG. 4B or be circular, elliptical or rectangular with rounded edges.

Referring again to FIG. 4A, the electrode 226 has an electrode base plate 226A that is in contact with the interconnect 216 and vertical electrode portions 226B as shown. A vertical thickness (along Y-direction) of the electrode base plate 226A may be substantially the same as a lateral thickness (along X-direction) of the vertical electrode portions 226B. In an embodiment, the vertical electrode portion 226B has height, H_{E}, relative to the uppermost surface 218A that is between 100 nm and 1000 nm. The ratio between the height, H_{E}, and lateral width, W_{O}, is defined as an aspect ratio. In embodiments, the aspect ratio of the electrode 226 is between 5:1 to 20:1.

Electrode 228 has one or more features of the electrode 228. The electrode 228 has an electrode base plate 228A that is in contact with the interconnect 216 and vertical electrode portion 228B, as shown. A vertical thickness (along Y-direction) of the electrode base plate 228A may be substantially the same as a lateral thickness (along X-direction) of the vertical electrode portion 228B. In an embodiment, the vertical electrode portion 228B has height, H_{E}, relative to the uppermost surface 218A that is between 100 nm and 1000 nm. The ratio between the height, H_{E}, and lateral width, W_{O}, is defined as an aspect ratio. In embodiments, the aspect ratio of the electrode 228 is between 5:1 to 20:1.

FIG. 4B is a plan-view illustration through a line A-A′ of the structure in FIG. 4A. As shown, the electrode sidewall 226B encloses the opening 223, and electrode sidewall 228B encloses the opening 225. In the illustrative embodiment, the electrode sidewall 226B and electrode sidewall 228B follow the contours of the opening 223 and opening 225, respectively.

FIG. 5A illustrates the plan-view illustration of the structure in FIG. 4B following the formation of a mask 230 and etching of the dielectric layer 212, the insulator 210, and the dielectric 208 (212, 210 and 208 are under the mask 230 in the Figure). The insulator 206 is not etched. The mask 230 may be around all vertical electrode portions 226A and 228A (indicated by dashed lines). In an embodiment, a plasma etch process utilized to form the openings 223 and 225 described above may be utilized to etch the dielectric layer 212, the insulator 210, and the dielectric 208.

FIG. 5B illustrates the structure of FIG. 5A following the removal of the mask 230.

FIG. 6A illustrates plan-view illustration of the structure in FIG. 5B following the removal of the dielectric 212 and dielectric 208 (212 and 208 under the insulator 210). In an embodiment, a wet chemical etch is utilized to remove the dielectric 212 and 208 selectively to the electrodes 226 and 228 and the insulator 206 and insulator 210. In the illustrative embodiment, a boundary 210A of the insulator layer 210 encloses the electrodes 226 and 228. The wet chemical etch process isotropically etches the dielectric 208 inside the boundary 210A including regions between electrodes 226 and 228.

FIG. 6B is a cross-sectional illustration of the plan view structure in FIG. 6A, along the line A-A′. The wet chemical etch process described above isotropically etches the dielectric 208 inside the boundary 210A including regions between electrodes 226 and 228. As shown removal of dielectric 208 and dielectric 212 (not shown in Figure) enables back filling with a metal electrode layer. Back filling with a metal electrode layer enables formation of a double wall capacitor. Formation of a double wall capacitor increases the density of charge storage per unit (plan-view) area, as will be discussed further below.

Removal of the dielectric 208 and dielectric 212 forms a suspended insulator layer 210 adjacent to portions of the vertical electrode portions 226B and 228B. It is to be appreciated that the suspended insulator layer 210 provides mechanical support for the vertical electrode portions 226B and 228B.

In the illustrative embodiment, the insulator layer 210 is at a height H_{IL}, above the uppermost surface 218A. While one insulator layer 210 is shown in the Figure, depending on the desired height, H_{E} of each electrode 226 and 228, there may be more than one insulator layers and a dielectric above each of the one or more insulator layer to facilitate structural support for the vertical electrode portions 226B and 228B. Structural support from insulator layer 210 may prevent bowing and collapse of electrode portions 226B and 228B. Furthermore, when electrode portions 226B and 228B are not substantially vertical but follow a curved contour of openings 223 and 225 such as is illustrated further below, insulator layer 210 may prevent collapse of the electrode portions 226B and 228B.

It is to be appreciated that adhesion of vertical electrode portions 226B and 228B to sidewalls of insulator layer 206, as shown, facilitates support near a base of the electrodes 226 and 228. As such, adhesion between insulator layer 206 and vertical electrode portions 226B and 228B is advantageous for formation of electrodes with high aspect ratios, such as an aspect ratio between 20:1.

FIG. 6C is an isometric illustration of the structure in FIG. 6B. The electrodes 226 and 228 are supported by insulator layer 206 and insulator layer 210 as shown. With higher aspect ratio such as above 20:1, more insulator layers may be added between insulator layers 210 and 206.

FIG. 7 illustrates the structure of FIG. 6B following the formation of a dielectric insulator 232. In an embodiment, the deposition process includes an atomic layer deposition (ALD) process. The ALD process facilitates deposition of dielectric insulator 232 on underlying surfaces that are not directly visible from a line of sight directly above the insulator 210. In an embodiment, the dielectric insulator 232 may be annealed after deposition.

In the illustrative embodiment, the dielectric insulator 232 is deposited on boundary sidewall 210A, on uppermost surface 210B, and on lowermost surface 210C of the insulator 210 and on uppermost surface 218A of the dielectric 218.

As shown, the dielectric insulator 232 is conformally deposited on all exposed surfaces of the electrode 226 inside opening 223, such as on inner sidewalls 226C and on electrode base plate 226A, and on outer sidewalls 226D. The dielectric insulator 232 is also conformally deposited on all exposed surfaces of the electrode 228 inside opening 225, such as on inner sidewalls 228C, and on electrode base plate 228A, and on outer sidewalls 228D. It is to be appreciated that the dielectric insulator 232 is not on portions of sidewalls 226D and 228D that are directly adjacent to the insulator 210 and dielectric 218.

In an embodiment, the dielectric insulator 232 includes a material that can provide sufficient insulation against dielectric breakdown. In an embodiment, the dielectric insulator 232 includes a high-K dielectric layer (a layer with a dielectric constant greater than 4 for silicon dioxide). In one embodiment, the dielectric insulator 232 includes silicon oxy-nitride, hafnium oxide, zirconium oxide, hafnium silicate, hafnium oxy-nitride, titanium oxide, aluminum oxide or lanthanum oxide. In another embodiment, however, the dielectric insulator 232 includes a material that is different from the material of the insulator layer 210. In embodiments, the dielectric insulator 232 has a relative permittivity of at least 10. In some such embodiments, the dielectric insulator 232 has a relative permittivity that is greater than a relative permittivity of the insulator layer 210.

The dielectric insulator 232 may be deposited to a thickness that facilitates a total capacitance of at least [XFarads]. In exemplary embodiments the dielectric insulator 232 is deposited to a thickness between 5 nm-15 nm.

FIG. 8A illustrates the structure of FIG. 7 following the formation of an electrode layer 234 on the dielectric insulator 232. In an embodiment, the electrode layer 234 is deposited using an ALD process. The ALD process facilitates deposition of the electrode layer 234 below surfaces that are not directly visible from a line of sight above the insulator 210. In some embodiments, after formation of the electrode layer 234, a fill metal may be deposited on the electrode layer 234, where the fill metal and portions of the electrode layer 234 are planarized. In other embodiments, the electrode layer 234 may be planarized after depositing a substantially thick layer. In embodiments, the electrode layer 234 includes titanium, tantalum ruthenium, nitrides of tantalum (for e.g., tantalum nitride) or nitrides of titanium (for e.g., titanium nitride).

As shown, the electrode layer 234 is conformally deposited on the dielectric insulator 232 inside opening 223, on the dielectric insulator 232 adjacent to sidewalls 226C, on the dielectric insulator 232 on the electrode base plate 226A, and on the dielectric insulator 232 on the outer sidewalls 226D. As illustrated, the electrode layer 234 is conformally deposited on the dielectric insulator 232 inside opening 225, on the dielectric insulator 232 adjacent to sidewalls 228C, on the dielectric insulator 232 on the electrode base plate 228A, and on the dielectric insulator 232 on the outer sidewalls 228D.

It is to be appreciated that the electrode layer 234 is not adjacent to portions of outer sidewalls 226D and 228D where the insulator layer 210 and the dielectric 218 intervene. Thus, the coverage of the electrode layer 234 is not the same between the inner and outer sidewalls of the electrode 226 or between the inner and outer sidewalls of the electrode 228. Unequal coverage may impact the electric field produced between the electrode layer 234 and each of the electrodes 226 and 228 during operation. To this end, the insulator layer 210 and 218 may each have a thickness that is sufficiently thin for advantageous operation while providing structural support.

As shown, the electrode layer 234 extends continuously between the electrodes 226 and 228. Deposition of the electrode layer 234 completes the process to form double wall capacitors having a shared electrode.

FIG. 8B illustrates a plan view along a line A-A′ of the structure in FIG. 8A. The presence of the electrode layer 234 adjacent to the inner and outer sidewalls 226C and 226D with a dielectric insulator 232 therebetween forms a double wall capacitor 236 (within dashed lines). Similarly, the presence of the electrode layer 234 adjacent to the inner and outer sidewalls 228C and 228D with a dielectric insulator 232 therebetween forms a double wall capacitor 238 (within dashed lines). As the electrode 234 surrounds each of the outer sidewalls 226D and 228D, the total surface area of the electrode layer 234 around each of the electrodes 226 and 228 is substantially increased. The total surface area is increased in the illustrative embodiment, compared to if the electrode layer 234 was only confined inside each of the electrodes 226 and 228. The total capacitance is determined by the charge stored on the electrodes 234 and 226 for capacitor 236, and by the charge stored on the electrodes 234 and 226 for capacitor 236. Formation of double wall capacitors 236 and 238 increases the density of charge storage per unit (plan-view) area.

FIG. 8C is a cross-sectional illustration along a line B-B′ of the structure in FIG. 8A, within a space between the electrodes 226 and 228. As shown, the dielectric insulator 232 and the electrode layer 234 wraps around the insulator layer 210 within a space between the electrodes 226 and 228 (in planes that are in and out of the Figure, not shown in FIG. 8B).

In the illustrative embodiment in FIG. 8A the electrode sidewalls 226C, 226D, 228C and 228D are substantially vertical. In other embodiments, the sidewalls 226C, 226D, 228C and 228D are tapered, slanted or curved as described above. As described above, non-vertical sidewalls, are indicative of the process utilized to form the electrodes 226 and 228.

FIG. 9A is a cross sectional illustration of integrated circuit capacitor array 900, where electrodes 226 and 228 have sidewalls that are curved. As shown, sidewalls 226C and 226D of electrode 226 are uniformly curved from a top end 226E to the base electrode portion 226A. The dielectric insulator 232 substantially matches the contour of the interior sidewalls 226C and exterior sidewalls 226D. As illustrated, sidewalls 228C and 228D of electrode 228 are uniformly curved from a top end 228E to the base electrode portion 228A. The dielectric insulator 232 substantially matches a contour of the interior sidewalls 228C and exterior sidewalls 228D.

In the illustrative embodiment, the insulator layers 210 and 206 follow the contour of the exterior sidewalls 226D and 228D. As shown, the lateral distance, D_{L}, between the electrodes 226 and 228, varies as a function of the height, H_{E}. D_{L}, is a maximum at the bottom of insulator layer 206. Because each insulator layer 210 and 206 are in contact with sidewalls 226D and 228D, each have a lateral width that corelates with lateral distance, D_{L}. In the illustrative embodiment, the insulator layer 210 has a lateral thickness, W₁, that is less than a lateral thickness, W₂, of the insulator layer 206 spanning the distance between the electrodes 226 and 228. In embodiments, W₁ is between 25 nm and 35 nm, and W₂ is between 30 nm and 45 nm.

FIG. 9B and FIG. 9C are plan-view illustrations through the line A-A′, and B-B′, respectively, of the structure in FIG. 9A. In the illustrative embodiments, the plan view shape of the electrodes 226 and 228 are substantially rectangular. In other embodiments, the plan view shape of the electrodes 226 and 228 are substantially circular or elliptical. As shown, a plan view area spanned by the top portion 226E of the electrode 226, illustrated in FIG. 9B, is greater than a plan view area of the base electrode portion 226A illustrated in FIG. 9C. A lateral width, W_{B}, of base portion 226A, shown in FIG. 9C, is less than a lateral width, W_{T}, of the top portion 226E, shown in FIG. 9B.

Referring again to FIG. 9A, in the illustrative embodiment, when the base electrode 226A or 228A have a plan view area that is circular, the radius of the electrode 226 or electrode 228 increases with height, H_{E}.

FIG. 10 illustrates the structure of FIG. 8 following the formation of a conductive interconnect 240 in contact with the electrode layer 234. In an embodiment, a dielectric 242 is deposited on the electrode layer 234. An opening may be formed in the dielectric 242 by a mask and etch process. In an embodiment, an adhesive liner layer 240A is deposited on the electrode layer 234 and on sidewalls and on uppermost surface of the dielectric 242. A fill metal 240B may be deposited on the adhesive liner layer 240A. The fill metal 240B and the adhesive liner layer 240A may be planarized and removed from above the dielectric 242 to form conductive interconnect 240.

In accordance with embodiments of the present disclosure the integrated circuit capacitor array 1000, includes a plurality of electrodes 226 and 228, where individual ones of the electrodes 226 and 228 are substantially cylindrical with base electrode portions 226A and 228A, respectively. The electrodes 226 and 228 are over a substrate 1002 and each have an open top end over the base electrode portions 226A and 228A. The integrated circuit capacitor array 1000 further includes a dielectric material layer, (herein insulator layer 210) spanning a distance between the electrode 226 and electrode 226, where the insulator layer 210 is absent from an interior of the electrodes 226 and 228. As shown, the insulator layer 210 is substantially planar and bifurcates a height, H_{E}, of electrodes 226 and 228. A second dielectric material layer (herein dielectric insulator layer 232) lines the interior of the electrodes 226 and 228, and lines portions of an exterior sidewalls 226D and 228D of the electrode 226 and 228, respectively above and below the insulator layer 210. The integrated circuit capacitor array 1000 further includes electrode layer 234, wherein the electrode layer 234 is within the interior of the electrodes 226 and 228, and around the exterior sidewalls 226D and 228D of the electrodes 226 and 228 above and below the insulator layer 210. In the illustrative embodiment, the electrode layer 234 extends continuously on a plane above transistors 1004 and 1006.

In some embodiments, the integrated circuit capacitor array 1000 is above a plurality of transistor structures such as transistors 1004 and 1006. Depending on embodiments, transistors 1004 and 1006 may be a thin-film-transistor (TFT) fabricated on a non-silicon substrate 1002, a non-planar transistor or nanowire transistor fashioned from silicon or non-silicon materials.

In the illustrative embodiment, the electrode 226 of the double walled capacitor structure 236 (inside dashed box) is coupled with a terminal 1008 that is in contact with a source or drain of the transistor 1004 through the interconnect 214. As shown, the electrode 228 is coupled with a terminal 1010 that is in contact with a source or drain of the transistor 1006 through the interconnect 216. Interconnect structure 240, transistors 1004 and 1006 may be energized and operated in unison to charge and discharge the integrated circuit capacitor array 1000. As shown, the conductive interconnect 214 and transistor are adjacent to a dielectric 1012. In one or more embodiments, the dielectric 1012 includes any material that has sufficient dielectric strength to provide electrical isolation. Materials may include silicon and one or more of oxygen, nitrogen or carbon such as silicon dioxide, silicon nitride, silicon oxynitride, carbon doped nitride or carbon doped oxide.

FIG. 11 is an enhanced cross-sectional illustration of the double walled capacitor 236 of the integrated circuit capacitor array 1000 coupled with transistor 1004 depicted in FIG. 10. In the illustrative embodiment, the transistor 1004 is on a substrate 1102 and has a gate 1103, a source region 1104, and a drain region 1106. In the illustrative embodiment, an isolation 1108 is adjacent to the source region 1104, drain region 1106 and portions of the substrate 1102. In some implementations of the disclosure, such as is shown, a pair of sidewall spacers 1110 are on opposing sides of the gate 1103.

The transistor 1004 further includes a source contact 1112 above and electrically coupled to the source region 1104, drain contact 1008 above and electrically coupled to the drain region 1106 and a gate contact 1116 above and electrically coupled to the gate 1103, as is illustrated. The transistor 1004 also includes dielectric 1012 adjacent to the gate 1103, source region 1104, drain region 1106, isolation 1108, sidewall spacers 1110, source contact 1112, drain terminal 1008 and gate contact 1116. In embodiments, source contact 1112 and gate contact 1116 are coupled with external circuit elements (not shown) through conductive interconnects 1118 and conductive interconnect 1120, respectively.

The electrode 226 is further coupled with the drain contact 1008 of the transistor 1004 through the conductive interconnect 214. As shown the conductive interconnect 214 is on and coupled with the drain contact 1008 of the transistor 1004. In other embodiments, one or more layers of interconnects exist between conductive interconnect 214 and the drain contact 1008.

In an embodiment, the underlying substrate 1102 represents a surface used to manufacture integrated circuits. Suitable substrate 1102 includes a material such as single crystal silicon, polycrystalline silicon and silicon on insulator (SOI), as well as substrates formed of other semiconductor materials. In some embodiments, the substrate 1102 may also include semiconductor materials, metals, dielectrics, dopants, and other materials commonly found in semiconductor substrates.

In an embodiment, the transistor 1004 associated with substrate 1102 are metal-oxide-semiconductor field-effect transistors (MOSFET or simply MOS transistors), fabricated on the substrate 1102. In some embodiments, the transistor 1004 is an access transistor 1004. In various implementations of the disclosure, the transistor 1004 may be planar transistors, nonplanar transistors, or a combination of both. Nonplanar transistors include FinFET transistors such as double-gate transistors and tri-gate transistors.

In some embodiments, gate 1103 includes at least two layers, a gate dielectric layer 1103A and a gate electrode 1103B. The gate dielectric layer 1103A may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer 1103A to improve its quality when a high-k material is used.

The gate electrode 1103B of the access transistor 1004 of substrate 1102 is formed on the gate dielectric layer 1103A and may consist of at least one P-type work function metal or N-type work function metal, depending on whether the transistor is to be a PMOS or an NMOS transistor. In some implementations, the gate electrode 1103B may consist of a stack of two or more metal layers, where one or more metal layers are work function metal layers and at least one metal layer is a conductive fill layer.

For a PMOS transistor, metals that may be used for the gate electrode 1103B include, but are not limited to, ruthenium, palladium, platinum, cobalt, nickel, and conductive metal oxides, e.g., ruthenium oxide. A P-type metal layer will enable the formation of a PMOS gate electrode with a work function that is between about 4.6 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a work function that is between about 3.6 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode 1103B may simply be a planar layer that is substantially parallel to the top surface of the substrate and does not include sidewall portions substantially perpendicular to the top surface of the substrate. In further implementations of the disclosure, the gate electrode may consist of a combination of U-shaped structures and planar, non-U-shaped structures. For example, the gate electrode 1103B may consist of one or more U-shaped metal layers formed atop one or more planar, non-U-shaped layers.

The sidewall spacers 1110 may be formed from a material such as silicon nitride, silicon oxide, silicon carbide, silicon nitride doped with carbon, and silicon oxynitride. Processes for forming sidewall spacers include deposition and etching process operations. In an alternate implementation, a plurality of spacer pairs may be used, for instance, two pairs, three pairs, or four pairs of sidewall spacers may be formed on opposing sides of the gate stack. As shown, the source region 1104 and drain region 1106 are formed within the substrate adjacent to the gate stack of each MOS transistor. The source region 1104 and drain region 1106 are generally formed using either an implantation/diffusion process or an etching/deposition process. In the former process, dopants such as boron, aluminum, antimony, phosphorous, or arsenic may be ion-implanted into the substrate to form the source region 1104 and drain region 1106. An annealing process that activates the dopants and causes them to diffuse further into the substrate typically follows the ion implantation process. In the latter process, the substrate 1102 may first be etched to form recesses at the locations of the source and drain regions. An epitaxial deposition process may then be carried out to fill the recesses with material that is used to fabricate the source region 1104 and drain region 1106. In some implementations, the source region 1104 and drain region 1106 may be fabricated using a silicon alloy such as silicon germanium or silicon carbide. In some implementations, the epitaxially deposited silicon alloy may be doped in situ with dopants such as boron, arsenic, or phosphorous. In further embodiments, the source region 1104 and drain region 1106 may be formed using one or more alternate semiconductor materials such as germanium or a group III-V material or alloy. And in further embodiments, one or more layers of metal and/or metal alloys may be used to form the source region 1104 and drain region 1106.

In an embodiment, the source contact 1112, the drain contact 1008 and gate contact 1116 each include a liner layer and a fill metal on the liner layer. In an embodiment, the liner layer includes one or more of Ti, Ru or Al and the fill metal includes W or Ni.

In an embodiment, the conductive interconnect 1118 includes a liner layer 1118A and a fill metal 1118B on the liner layer 1118A, as shown. In an embodiment, the liner layer 1118A includes one or more of Ti, Ta, Ru or Al. The fill metal 1118B may include a material such as W or Cu.

In an embodiment, the conductive interconnect 1120 includes a liner layer 1120A and a fill metal 1120B on the liner layer 1120A, as shown. In an embodiment, the liner layer 1120A includes one or more of Ti, Ta, Ru or Al. The fill metal 1120B may include a material such as W or Cu.

The isolation 1108 may each include any material that has sufficient dielectric strength to provide electrical isolation. Materials may include silicon and one or more of oxygen, nitrogen or carbon such as silicon dioxide, silicon nitride, silicon oxynitride, carbon doped nitride or carbon doped oxide.

FIG. 12 illustrates a computing device 1200 in accordance with embodiments of the present disclosure. As shown, computing device 1200 houses a motherboard 1202. Motherboard 1202 may include a number of components, including but not limited to a processor 1201 and at least one communications chip 1204 or 1205. Processor 1201 is physically and electrically coupled to the motherboard 1202. In some implementations, communications chip 1205 is also physically and electrically coupled to motherboard 1202. In further implementations, communications chip 1205 is part of processor 1201.

Depending on its applications, computing device 1200 may include other components that may or may not be physically and electrically coupled to motherboard 1202. These other components include, but are not limited to, volatile memory (e.g., DRAM, eDRAM), non-volatile memory (e.g., ROM), flash memory, a graphics processor, a digital signal processor, a crypto processor, a chipset 1206, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

Communications chip 1205 enables wireless communications for the transfer of data to and from computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communications chip 1205 may implement any of a number of wireless standards or protocols, including but not limited to Wi-Fi (IEEE 801.11 family), WiMAX (IEEE 801.11 family), long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 1200 may include a plurality of communications chips 1204 and 1205. For instance, a first communications chip 1205 may be dedicated to shorter range wireless communications such as Wi-Fi and Bluetooth and a second communications chip 1204 may be dedicated to longer range wireless communications such as GPS, EDGE, GPRS, CDMA, WiMAX, LTE, Ev-DO, and others.

Processor 1201 of the computing device 1200 includes an integrated circuit die packaged within processor 1201. In some embodiments, the integrated circuit die of processor 1201 includes one or more interconnect structures, non-volatile memory devices, and transistors coupled with capacitors such as integrated circuit capacitor array 1000 described in FIGS. 10. Referring again to FIG. 12, the term “processor” may refer to any device or portion of a device that processes electronic data from registers and/or memory to transform that electronic data into other electronic data that may be stored in registers and/or memory.

Communications chip 1205 also includes an integrated circuit die packaged within communication chip 1205. In another embodiment, the integrated circuit die of communications chips 1204, 1205 includes one or more interconnect structures, non-volatile memory devices, capacitors such as integrated circuit capacitor array 1000 described above, and transistors coupled with capacitors such as transistor 1004 coupled with double wall capacitor 236 described in FIGS. 10 and 11. Referring again to FIG. 12, depending on its applications, computing device 1200 may include other components that may or may not be physically and electrically coupled to motherboard 1202. These other components may include, but are not limited to, volatile memory (e.g., DRAM, eDRAM) 1207, 1208, non-volatile memory (e.g., ROM) 1210, a graphics CPU 1212, flash memory, global positioning system (GPS) device 1213, compass 1214, a chipset 1206, an antenna 1216, a power amplifier 1209, a touchscreen controller 1211, a touchscreen display 1217, a speaker 1215, a camera 1203, and a battery 1219, as illustrated, and other components such as a digital signal processor, a crypto processor, an audio codec, a video codec, an accelerometer, a gyroscope, and a mass storage device (such as hard disk drive, solid state drive (SSD), compact disk (CD), digital versatile disk (DVD), and so forth), or the like. In further embodiments, any component housed within computing device 1200 and discussed above may contain a stand-alone integrated circuit memory die that includes one or more arrays of NVM devices.

In various implementations, the computing device 1200 may be a laptop, a netbook, a notebook, an Ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device 1200 may be any other electronic device that processes data.

FIG. 13 illustrates an integrated circuit (IC) structure 1300 that includes one or more embodiments of the disclosure. The integrated circuit (IC) structure 1300 is an intervening substrate used to bridge a first substrate 1302 to a second substrate 1304. The first substrate 1302 may be, for instance, an integrated circuit die. The second substrate 1304 may be, for instance, a memory module, a computer mother, or another integrated circuit die. Generally, the purpose of an integrated circuit (IC) structure 1300 is to spread a connection to a wider pitch or to reroute a connection to a different connection. For example, an integrated circuit (IC) structure 1300 may couple an integrated circuit die to a ball grid array (BGA) 1307 that can subsequently be coupled to the second substrate 1304. In some embodiments, the first substrate 1302 and the second substrate 1304 are attached to opposing sides of the integrated circuit (IC) structure 1300. In other embodiments, the first substrate 1302 and the second substrate 1304 are attached to the same side of the integrated circuit (IC) structure 1300. And in further embodiments, three or more substrates are interconnected by way of the integrated circuit (IC) structure 1300.

The integrated circuit (IC) structure 1300 may be formed of an epoxy resin, a fiberglass-reinforced epoxy resin, a ceramic material, or a polymer material such as polyimide. In further implementations, the integrated circuit (IC) structure may be formed of alternate rigid or flexible materials that may include the same materials described above for use in a semiconductor substrate, such as silicon, germanium, and other group III-V and group IV materials.

The integrated circuit (IC) structure may include metal interconnects 1308 and vias 1310, including but not limited to through-silicon vias (TSVs) 1312. The integrated circuit (IC) structure 1300 may further include embedded devices 1314, including both passive and active devices. Such embedded devices 1314 include transistors, resistors, inductors, fuses, diodes and transformers. Such embedded devices 1314 further include capacitors such as integrated circuit capacitor array 1000, and transistors coupled with capacitors such as transistor 1004 integrated with double wall capacitor 236 described in FIGS. 10 and 11. Referring again to FIG. 13, the integrated circuit (IC) structure 1300 may further include embedded devices 1314 such as one or more resistive random-access devices, sensors, and electrostatic discharge (ESD) devices. More complex devices such as radiofrequency (RF) devices, power amplifiers, power management devices, antennas, arrays, sensors, and MEMS devices may also be formed on the integrated circuit (IC) structure 1300.

Thus, semiconductor structures having integrated circuit capacitor array for memory applications and methods to form the same have been disclosed.

In a first example, an integrated circuit capacitor array includes a plurality of first electrodes, wherein individual ones of the first electrodes are substantially cylindrical with a base over a substrate and an open top end over the base. A first dielectric material layer spans a distance between the first electrodes but is absent from an interior of the first electrodes, where the first dielectric material layer is substantially planar and bifurcates a height of first electrodes. A second dielectric material layer lines the interior of the first electrodes, and lines portions of an exterior of the first electrodes above and below the first dielectric material layer and a second electrode is within the interior of the first electrodes and is around the exterior of the first electrodes above and below the first dielectric material layer.

In second examples, for any of first example, the first dielectric material layer has a thickness less than 400 nm and the second dielectric material layer has a thickness less than 25 nm.

In third examples, for any of the first through second examples, the first dielectric material layer has a relative permittivity lower than the second dielectric material layer.

In fourth examples, for any of the first through third examples, the second dielectric material layer has a relative permittivity greater than 9.

In fifth examples, for any of the first through fourth examples, the second dielectric and the second electrode wraps around the first dielectric material layer within a space between the first electrodes.

In sixth examples, for any of the first through fifth examples, the base has a rectangular, circular or an elliptical shape.

In seventh examples, for any of the first through sixth examples, the open top end of each of the plurality of electrodes has an area that is greater than an area of the base of each of the plurality of electrodes.

In eighth examples, for any of the first through seventh examples, the base is circular and the radius of the first electrodes increase with height as measured from the base.

In ninth examples, for any of the first through eighth examples, the integrated circuit capacitor array further comprises an insulator layer adjacent to the base of each of the plurality of first electrodes.

In tenth examples, for any of the first through eighth examples, the insulator layer has a lateral thickness that is greater than a lateral thickness of first dielectric material layer spanning the distance between the first electrodes.

In eleventh examples, for any of the first through eighth examples, the electrodes have a height as measured from the base, wherein the height is between 100 nm and 1000 nm.

In twelfth examples, for any of the first through eighth examples, the individual ones of the plurality of first electrodes are each coupled to a conductive interconnect.

In thirteenth examples, for any of the first through eighth examples, the second electrode is coupled to a conductive interconnect above the second electrode or adjacent to the plurality of first electrodes.

In a fourteenth example, a method to fabricate an integrated circuit capacitor array includes fabricating a material layer stack above a substrate, the material layer stack including a first insulator layer, a first dielectric layer on the first insulator layer, a second insulator layer on the first dielectric layer and a second dielectric layer on the second insulator layer. The method further includes etching the material layer stack to form a plurality of openings in the material layer stack, depositing a first electrode layer into each of the plurality of openings to form a plurality of cylindrical electrodes with a base over the substrate and an open top end over the base and etching the first dielectric layer and the second dielectric layer selectively to the cylindrical electrodes, selectively to the first insulator layer and to the second insulator layer, wherein the etching forms a suspended second insulator layer. The method further includes depositing a dielectric insulator layer to line the interior of the cylindrical electrodes, and line portions of an exterior of the cylindrical electrodes above and below the suspended second insulator layer and depositing a second electrode layer on the dielectric insulator layer filling the interior of the cylindrical electrodes, around the exterior of the cylindrical electrodes above and below the suspended second insulator layer.

In fifteenth examples, for any of the fourteenth example, prior to etching the first dielectric and the second dielectric selectively to the cylindrical electrodes, the material layer stack is patterned into a block, wherein the block exposes sidewalls of the first dielectric layer and the second dielectric layer.

In sixteenth examples, for any of the fourteenth through fifteenth examples, etching the material layer stack forms a plurality of openings comprising a taper.

In seventeenth examples, an integrated circuit memory device includes a transistor above a substrate. The transistor includes a source and a drain, a gate therebetween, a first conductive interconnect coupled with the drain and a second conductive interconnect coupled with the drain. A capacitor is coupled with the first or the second conductive interconnect where the capacitor includes a first electrode, where the first electrode is substantially cylindrical with a base over the first or the second conductive interconnect and an open top end over the base. The capacitor further includes a first dielectric material layer adjacent to an exterior of the first electrode and absent from an interior of the first electrode, wherein the first dielectric material layer is substantially planar and bifurcates a height of first electrode. The capacitor further includes a second dielectric material layer, where the second dielectric material layer lines the interior of the first electrode, and lines portions of an exterior of the first electrode above and below the first dielectric material layer. A second electrode is within the interior of the first electrode and is around the exterior of the first electrode above and below the first dielectric material layer.

In eighteenth examples, for any of the seventeenth example, the transistor is a thin film transistor or a fin-field emission transistor (fin-FET).

In nineteenth examples, for any of the seventeenth through eighteenth examples, the second electrode extends beyond lateral bounds of the transistor.

In twentieth example, for any of the seventeenth through nineteenth examples, the capacitor is a first capacitor and the transistor is a first transistor and the second electrode extends to couple with a second capacitor coupled with the second transistor.

What is claimed is:

1. An integrated circuit capacitor array, comprising:
a plurality of first electrodes, wherein individual ones of the first electrodes are substantially cylindrical with a base over a substrate and an open top end over the base;
a first dielectric material layer spanning a distance between the first electrodes and absent from an interior of the first electrodes, wherein the first dielectric material layer is substantially planar and bifurcates a height of the first electrodes;
a second dielectric material layer, wherein the second dielectric material layer lines the interior of the first electrodes, and lines portions of an exterior of the first electrodes above and below the first dielectric material layer; and
a second electrode, wherein the second electrode is within the interior of the first electrodes and is around the exterior of the first electrodes above and below the first dielectric material layer.

2. The integrated circuit capacitor array of claim 1, wherein the first dielectric material layer has a thickness less than 400 nm and the second dielectric material layer has a thickness less than 25 nm.

3. The integrated circuit capacitor array of claim 1, wherein the first dielectric material layer has a relative permittivity lower than the second dielectric material layer.

4. The integrated circuit capacitor array of claim 1, wherein the second dielectric material layer has a relative permittivity greater than 9.

5. The integrated circuit capacitor array of claim 1, wherein the second dielectric and the second electrode wraps around the first dielectric material layer within a space between the first electrodes.

6. The integrated circuit capacitor array of claim 1, wherein the base has a rectangular, circular or an elliptical shape.

7. The integrated circuit capacitor array of claim 1, wherein the open top end of each of the plurality of electrodes has an area that is greater than an area of the base of each of the plurality of electrodes.

8. The integrated circuit capacitor array of claim 1, wherein the base is circular and the radius of the first electrodes increase with height as measured from the base.

9. The integrated circuit capacitor array of claim 1, further comprises an insulator layer adjacent to the base of each of the plurality of first electrodes.

10. The integrated circuit capacitor array of claim 9, wherein the insulator layer has a lateral thickness that is greater than a lateral thickness of first dielectric material layer spanning the distance between the first electrodes.

11. The integrated circuit capacitor array of claim 9, wherein the electrodes have a height as measured from the base, wherein the height is between 100 nm and 1000 nm.

12. The integrated circuit capacitor array of claim 1, wherein the individual ones of the plurality of first electrodes are each coupled to a conductive interconnect.

13. The integrated circuit capacitor array of claim 1, wherein the second electrode is coupled to a conductive interconnect above the second electrode or adjacent to the plurality of first electrodes.

14. A method to fabricate an integrated circuit capacitor array, the method comprising:
fabricating a material layer stack above a substrate, the material layer stack comprising a first insulator layer, a first dielectric layer on the first insulator layer, a second insulator layer on the first dielectric layer and a second dielectric layer on the second insulator layer;
etching the material layer stack to form a plurality of openings in the material layer stack;
depositing a first electrode layer into each of the plurality of openings to form a plurality of cylindrical electrodes with a base over the substrate and an open top end over the base;
etching the first dielectric layer and the second dielectric layer selectively to the cylindrical electrodes, selectively to the first insulator layer and to the second insulator layer, wherein the etching forms a suspended second insulator layer;
depositing a dielectric insulator layer to line the interior of the cylindrical electrodes, and line portions of an exterior of the cylindrical electrodes above and below the suspended second insulator layer; and
depositing a second electrode layer on the dielectric insulator layer filling the interior of the cylindrical electrodes, around the exterior of the cylindrical electrodes above and below the suspended second insulator layer.

15. The method of claim 14, wherein prior to etching the first dielectric and the second dielectric selectively to the cylindrical electrodes, the material layer stack is patterned into a block, wherein the block exposes sidewalls of the first dielectric layer and the second dielectric layer.

16. The method of claim 14, wherein etching the material layer stack forms a plurality of openings comprising a taper.

17. An integrated circuit memory device comprising:
a transistor above a substrate, the transistor comprising:
a source and a drain;
a gate therebetween;
a first conductive interconnect coupled with the drain; and
a second conductive interconnect coupled with the drain; and
a capacitor, coupled with the first or the second conductive interconnect, the capacitor comprising:
a first electrode, wherein the first electrode is substantially cylindrical with a base over the first or the second conductive interconnect and an open top end over the base;
a first dielectric material layer adjacent to an exterior of the first electrode and absent from an interior of the first electrode, wherein the first dielectric material layer is substantially planar and bifurcates a height of first electrode;
a second dielectric material layer, wherein the second dielectric material layer lines the interior of the first electrode, and lines portions of an exterior of the first electrode above and below the first dielectric material layer; and
a second electrode, wherein the second electrode is within the interior of the first electrode and is around the exterior of the first electrode above and below the first dielectric material layer.

18. The integrated circuit memory device of claim 17, wherein the transistor is a thin film transistor or a fin-field emission transistor (fin-FET).

19. The integrated circuit memory device of claim 17, wherein the second electrode extends beyond lateral bounds of the transistor.

20. The integrated circuit memory device of claim 19, wherein the capacitor is a first capacitor and the transistor is a first transistor and the second electrode extends to couple with a second capacitor coupled with the second transistor.
